(19) United States
(12) Patent Application Publication
(10) Pub. No.: US 2026/0358390 A1
(43) Pub. Date: Nov. 12, 2026

(54) WIDEBAND MEASUREMENT METHOD AND APPARATUS FOR POWER SYSTEM, AND COMPUTER DEVICE

(71) Applicant: ELECTRIC POWER RESEARCH INSTITUTE, CHINA SOUTHERN POWER GRID, Guangzhou, Guangdong (CN)

(72) Inventors: Wei WU, Guangzhou, Guangdong (CN); Baorong ZHOU, Guangzhou, Guangdong (CN); Chao HONG, Guangzhou, Guangdong (CN); Hong RAO, Guangzhou, Guangdong (CN); Dehui ZENG, Guangzhou, Guangdong (CN); Yuming LIU, Guangzhou, Guangdong (CN)

(73) Assignee: ELECTRIC POWER RESEARCH INSTITUTE, CHINA SOUTHERN POWER GRID, Guangzhou, Guangdong (CN)

(21) Appl. No.: 19/123,055

(22) PCT Filed: Mar. 12, 2024
(86) PCT No.: PCT/CN2024/081105

§ 371 Date: Apr. 21, 2025

(30) Foreign Application Priority Data
Oct. 25, 2023 (CN) 202311387144.2

(51) Int. Cl. G01R 23/16

(52) U.S. Cl. CPC G01R 23/16

(57) ABSTRACT

A wideband measurement method for a power system, a wideband measurement apparatus for a power system, and a computer device are provided, relating to the technical field of wideband measurement. The method includes: obtaining a target electrical signal; decomposing the target electrical signal into multiple single-frequency signal components in a time domain by using a local mean decomposition algorithm; determining an instantaneous frequency of the signal component; determining a time-frequency conversion algorithm and a time-frequency conversion parameter based on the instantaneous frequency; performing time-frequency conversion on the signal component by using the time-frequency conversion algorithm based on the time-frequency conversion parameter; and obtaining a wideband spectrum including frequency-domain information corresponding to all the multiple single-frequency signal components.

The present application claims priority to Chinese Patent Application No. 202311387144.2, titled “WIDEBAND MEASUREMENT METHOD AND APPARATUS FOR POWER SYSTEM, AND COMPUTER DEVICE”, filed on Oct. 25, 2023 with the China National Intellectual Property Administration, which is incorporated herein by reference in its entirety.

### FIELD

The present disclosure relates to the technical field of wideband measurement, and in particular to a wideband measurement method for a power system, a wideband measurement apparatus for a power system, and a computer device.

### BACKGROUND

In new power systems, large-scale new energy generation, high-voltage direct current transmission, and high-power direct-current loads are developing rapidly. The degree of power electronicization of in the “source-grid-load” links of the power system is gradually increased, and the power system is developing towards a direction of high-proportion new energy generation and high-proportion of power electronic devices. With large-scale integration of new energy into the power grid and high proportion of power electronic devices connected, new oscillation problems occurs in the system due to the interaction between new energy units and the power grid, causing wideband oscillations with frequencies ranging from a few Hz to thousands of Hz. In the future, with the construction and development of new power systems, the wideband oscillation problem will become increasingly severe, seriously threatening the safe and reliable operation of the power grid.

Wideband oscillation is fundamentally different from the conventional power angle oscillation, voltage oscillation and frequency oscillation in terms of mechanism. From the perspective of signal processing, when a wideband oscillation occurs, the voltage signals and the current signals of the system contain non-power frequency components with large amplitudes, and these non-power frequency components with large amplitudes cause distortion of the voltage signals and the current signals, resulting in abnormal states of the power system. Therefore, it is required to observe the system accurately to perform accurate spectrum analysis on electrical signals in a wide frequency range. The spectrum analysis methods according to the conventional technology have the problems of insufficient accuracy and slow calculation speed in a wide frequency range.

### SUMMARY

According to the present disclosure, at least one of the technical defects mentioned above can be solved, especially the problems of insufficient accuracy and slow calculation speed in a wide frequency range in the spectrum analysis methods according to the conventional technology.

In a first aspect, a wideband measurement method for a power system is provided according to the present disclosure. The method includes:
obtaining a target electrical signal;
decomposing the target electrical signal into multiple single-frequency signal components in a time domain by using a local mean decomposition algorithm;
for each of the multiple single-frequency signal components,
   determining an instantaneous frequency of the signal component;
   determining a time-frequency conversion algorithm and a time-frequency conversion parameter based on the instantaneous frequency; and
   performing time-frequency conversion on the signal component by using the time-frequency conversion algorithm based on the time-frequency conversion parameter; and
obtaining a wideband spectrum including frequency-domain information corresponding to all the multiple single-frequency signal components.

In an embodiment, the determining a time-frequency conversion algorithm based on the instantaneous frequency includes:
determining the time-frequency conversion algorithm as a discrete Fourier algorithm in a case that the instantaneous frequency is below a first threshold; and
determining the time-frequency conversion algorithm as a fast Fourier algorithm in a case that the instantaneous frequency is greater than the first threshold.

In an embodiment, the time-frequency conversion parameter includes a sampling window type, and the determining a time-frequency conversion parameter based on the instantaneous frequency includes:
determining the sampling window type as a rectangular window type in the case that the instantaneous frequency is below the first threshold;
determining the sampling window type as a Hanning window type in a case that the instantaneous frequency is greater than the first threshold and below a second threshold; and
determining the sampling window type as a Blackman window type in a case that the instantaneous frequency is greater than the second threshold and below a third threshold.

In an embodiment, the time-frequency conversion parameter includes a sampling window length, and the determining a time-frequency conversion parameter based on the instantaneous frequency includes:
determining a target cycle number based on a mapping relationship between instantaneous frequencies and cycle numbers;
determining a cycle length based on the instantaneous frequency; and
obtaining the sampling window length based on the cycle length and the target cycle number.

In an embodiment, the determining a target cycle number based on a mapping relationship between instantaneous frequencies and cycle numbers includes:
determining the target cycle number as a first number in the case that the instantaneous frequency is below the first threshold;
determining the target cycle number as a second number in the case that the instantaneous frequency is greater than the first threshold and below the second threshold, where the second number is greater than the first number; and
determining the target cycle number as a third number in the case that the instantaneous frequency is greater than the second threshold and below the third threshold, where the third number is greater than the first number and less than the second number.

In an embodiment, the first threshold is 100 Hz, the second threshold is 650 Hz, the third threshold is 2500 Hz, the first number is 2, the second number is 8, and the third number is 3.

In an embodiment, the decomposing the target electrical signal into multiple single-frequency signal components in a time domain by using a local mean decomposition algorithm includes:
using the target electrical signal as an intermediate electrical signal;
determining all local maximum points and local minimum points of the intermediate electrical signal;
performing cubic spline interpolation on the local maximum points to obtain an upper envelope function, and performing cubic spline interpolation on the local minimum points to obtain a lower envelope function;
obtaining a local mean function and a local envelope function in a current cycle based on the upper envelope function and the lower envelope function;
determining whether the local envelope function in the current cycle is equal to 1;
dividing a difference between the intermediate electrical signal and the local mean function by the local envelope function, and returning to the determining all local maximum points and local minimum points of the intermediate electrical signal, in a case that the local envelope function in the current cycle is not equal to 1;
multiplying the local envelope function in the current cycle and local envelope functions in all previous cycles to obtain an envelope signal, using the local mean function in the current cycle as a pure frequency modulation signal, and obtaining a signal component based on the envelope signal and the pure frequency modulation signal, in a case that the local envelope function in the current cycle is equal to 1;
determining whether an iteration end condition is met after obtaining the signal component;
subtracting the obtained signal component from the target electrical signal, and returning to the using the target electrical signal as an intermediate electrical signal, in a case that the iteration end condition is not met; and
ending the decomposing the target electrical signal into multiple single-frequency signal components in a case that the iteration end condition is met.

In an embodiment, the determining whether an iteration end condition is met includes:
determining that the iteration end condition is met in a case that the number of local maximum points and local minimum points in the obtained signal component is less than a first threshold; and
determining that the iteration end condition is not met in a case that the number of local maximum points and local minimum points in the obtained signal component is not less than the first threshold.

In a second aspect, a wideband measurement apparatus for a power system is provided according to the present disclosure. The apparatus includes: a data obtaining module, a signal decomposition module, a frequency determination module, a selection module, and a time-frequency conversion module. The data obtaining module is configured to obtain a target electrical signal. The signal decomposition module is configured to decompose the target electrical signal into multiple single-frequency signal components in a time domain by using a local mean decomposition algorithm. The frequency determination module is configured to determine, for each of the signal components, an instantaneous frequency of the signal component. The selection module is configured to determine, for each of the signal components, a time-frequency conversion algorithm and a time-frequency conversion parameter based on the instantaneous frequency. The time-frequency conversion module is configured to: perform, for each of the signal components, time-frequency conversion on the signal component by using the time-frequency conversion algorithm based on the time-frequency conversion parameter, and obtain a wideband spectrum including frequency-domain information corresponding to all the signal components.

In a third aspect, a computer device is provided according to the present disclosure. The computer device includes: one or more processors and a memory. The memory stores computer-readable instructions. The computer-readable instructions, when executed by the one or more processors, cause the one or more processors to perform the wideband measurement method for a power system described in the above embodiments.

It can be seen from the above technical solutions that the embodiments of the present disclosure have the following advantages.

Based on the above embodiments, the target electrical signal is decomposed into signal components having different instantaneous frequencies by using a local mean decomposition algorithm. Each of the signal components fluctuates within a frequency band and has a specific instantaneous frequency, and power system analysis has different analysis requirements for signals having different instantaneous frequencies. Therefore, based on the instantaneous frequencies of the signal components, corresponding time-frequency conversion parameters are adaptively selected and time-frequency conversions are performed to obtain the entire wideband spectrum while meeting different analysis requirements. With the method according to the present disclosure, analysis requirements of different frequencies can be met, an appropriate calculation speed and calculation accuracy for the signals at all frequency points in the wideband spectrum can be ensured, effectively meeting wideband measurement requirements of new power systems and providing strong support for constructing a wide-area monitoring system for wideband oscillation in the power system.

### BRIEF DESCRIPTION OF THE DRAWINGS

In order to clearly illustrate technical solutions in the embodiments of the present disclosure or in the conventional technology, the drawings used in the description of the embodiments or the conventional technology are briefly described below. It is apparent that the drawings in the following description show only some embodiments of the present disclosure, and other drawings may be obtained by those skilled in the art based on the drawings without any creative efforts.

FIG. 1 is a flowchart of a wideband measurement method for a power system according to an embodiment of the present disclosure;

FIG. 2 is a schematic diagram of decomposing a simulation signal by using a local mean decomposition algorithm;

FIG. 3 is a schematic diagram of a frequency spectrum for analyzing a simulation signal by using a wideband measurement method for a power system according to the present disclosure;

FIG. 4 is a schematic diagram of modules of a wideband measurement apparatus for a power system according to an embodiment of the present disclosure; and

FIG. 5 is a schematic diagram showing an internal structure of a computer device according to an embodiment of the present disclosure.

### DETAILED DESCRIPTION OF THE EMBODIMENTS

The solutions in the embodiments of the present disclosure are described clearly and completely hereinafter in conjunction with the accompanying drawings in the embodiments of the present disclosure. It is apparent that the described embodiments are only some embodiments of the present disclosure, rather than all embodiments. Based on the embodiments in the present disclosure, all other embodiments obtained by those skilled in the art without creative efforts fall within the scope of protection of the present disclosure.

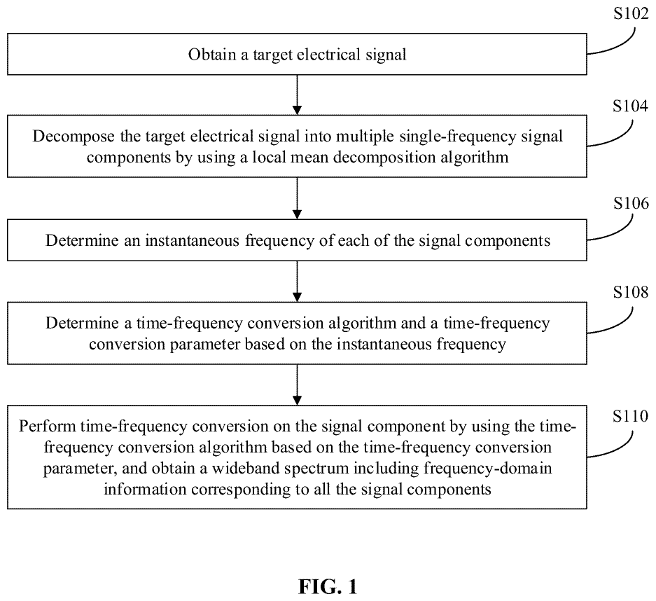

Please referring to FIG. 1, a wideband measurement method for a power system is provided according to the present disclosure. The wideband refers to a frequency band wider than the typical spectrum analysis range. The wideband measurement mainly includes decomposing complex time-domain signals into frequency-domain signals with different frequencies and determining frequency-domain information of the frequency-domain signals. The frequency-domain information generally includes amplitude, phase, frequency, and the like. The wideband measurement method for a power system in the embodiment includes the following steps S102 to S110.

In step S102, a target electrical signal is obtained.

It should be understood that the target electrical signal is an electrical signal that is obtained from a power system and on which spectrum analysis is to be performed. The target electrical signal may be a voltage signal or a current signal.

In step S104, the target electrical signal is decomposed into multiple single-frequency signal components in a time domain by using a local mean decomposition algorithm;

It should be understood that the target electrical signal is a non-stationary time-domain signal and includes multiple components. According to the conventional technology, the target electrical signal is directly converted to a frequency-domain signal by using a time-frequency conversion algorithm to obtain a frequency spectrum. However, since the target electrical signal includes multiple frequency components, the time-frequency conversion is directly performed on the target electrical signal without considering for the characteristics of different frequencies, resulting in low accuracy of the final result. With the local mean decomposition algorithm, the non-stationary time-domain signal including multiple components may be decomposed into multiple signal components, and each of the signal components has a different instantaneous frequency. Each of the signal components decomposed by using the local mean decomposition algorithm may be represented by a product function. The product function includes an envelope signal and a pure frequency modulation signal. The envelope signal represents an instantaneous amplitude of the product function, and the pure frequency modulation signal represents an instantaneous frequency of the product function. The signal components obtained by using the local mean decomposition algorithm have different instantaneous frequencies and have different analysis requirements. An appropriate time-frequency conversion algorithm and an appropriate time-frequency conversion parameter are adaptively selected to perform time-frequency conversion on each of the signal components, achieving a high frequency resolution and ensuring a high calculation speed.

In step S106, an instantaneous frequency is determined for each of the signal components.

For each of the signal components, the frequency of the signal component varies over time in the time domain, which may reflect the frequency of the signal component at the time instant when measurement is performed with the method according to the embodiment. In some embodiments, for each of signal components, an expression of the signal component may be obtained by using the local mean decomposition algorithm, then an inverse cosine of the signal component is calculated, and then the inverse cosine is derived over time and then is divided by 2π to obtain an expression of an instantaneous frequency. Then, the time instant when measurement is performed is substituted into the expression to obtain the instantaneous frequency.

In step S108, a time-frequency conversion algorithm and a time-frequency conversion parameter are determined based on the instantaneous frequency.

It should be understood that in the embodiment, before analyzing a signal component with a certain frequency, it is required to determine a corresponding time-frequency conversion algorithm based on the instantaneous frequency of the signal component and to determine a time-frequency conversion parameter, such as a sampling window length, a sampling window type, and an overlap coefficient, used in the time-frequency conversion algorithm. The time-frequency conversion parameter affects the calculation complexity, the frequency resolution, and the like. In the embodiment, the instantaneous frequencies of the signal components are different, and the requirements for signals with different frequencies are different in performing spectrum analysis on the power system. For example, some frequencies require priority for high timeliness priority, and some frequencies require priority for high accuracy. Therefore, after determining the instantaneous frequency of each of the signal components, a corresponding time-frequency conversion parameter may be configured according to the requirement of the frequency.

In step S110, time-frequency conversion is performed on the signal component by using the time-frequency conversion algorithm based on the time-frequency conversion parameter, and a wideband spectrum including frequency-domain information corresponding to all the signal components is obtained.

It should be understood that for each of the signal components, after the time-frequency conversion parameter and the time-frequency conversion algorithm are determined, the time-domain signal component may be converted to a frequency-domain signal. The conversion result includes an expression of the frequency-domain signal. Based on the expression, the frequency-domain signal of the signal component may be obtained, such as amplitude, phase, and frequency. Generally, an amplitude represents an energy level at a frequency, the wideband spectrum may be expressed as an image, such as an image formed by introducing the frequency-domain information of the signal components into a coordinate system with frequency as a horizontal axis and amplitude as a vertical axis. In addition, a same time-frequency conversion algorithm may be selected for different signal components, or different time-frequency conversion algorithms may be selected for different signal components, or a same time-frequency conversion algorithm may be selected for some signal components and different time-frequency conversion algorithms may be selected for some signal components.

With the wideband measurement method for a power system according to the embodiment, the target electrical signal is decomposed into signal components having different instantaneous frequencies by using a local mean decomposition algorithm. Each of the signal components fluctuates within a frequency band and has a specific instantaneous frequency, and power system analysis has different analysis requirements for signals having different instantaneous frequencies. Therefore, based on the instantaneous frequencies of the signal components, corresponding time-frequency conversion parameters are adaptively selected and time-frequency conversions are performed to obtain the entire wideband spectrum while meeting different analysis requirements. With the method according to the present disclosure, analysis requirements of different frequencies can be met, an appropriate calculation speed and calculation accuracy for the signals at all frequency points in the wideband spectrum can be ensured, effectively meeting wideband measurement requirements of new power systems and providing strong support for constructing a wide-area monitoring system for wideband oscillation in the power system.

In an embodiment, the time-frequency conversion algorithm is determined based on the instantaneous frequency by: (1) determining the time-frequency conversion algorithm as a discrete Fourier algorithm in a case that the instantaneous frequency is below a first threshold; and (2) determining the time-frequency conversion algorithm as a fast Fourier algorithm in a case that the instantaneous frequency is greater than the first threshold.

It should be understood that in the embodiment, different time-frequency conversion algorithms are determined based on the first threshold within a target frequency band range of wideband measurement. For a signal component with a low frequency, that is, a signal component with an instantaneous frequency below the first threshold, the discrete Fourier algorithm (DFT) is selected. For a signal component with a high frequency, that is, a signal component with an instantaneous frequency greater than the first threshold, the fast Fourier algorithm (FFT) is selected to improve processing efficiency. The discrete Fourier algorithm and the fast Fourier algorithm include original algorithms and improved algorithms.

In an embodiment, the time-frequency conversion parameter includes a sampling window type. The time-frequency conversion parameter is determined based on the instantaneous frequency by: (1) determining the sampling window type as a rectangular window type in the case that the instantaneous frequency is below the first threshold; (2) determining the sampling window type as a Hanning window type in a case that the instantaneous frequency is greater than the first threshold and below a second threshold; and (3) determining the sampling window type as a Blackman window type in a case that the instantaneous frequency is greater than the second threshold and below a third threshold.

It should be understood that in the embodiment, different time-frequency conversion algorithms are determined based on the first threshold and the second threshold within a target frequency band range of wideband measurement. For a signal component with a low frequency, that is, a signal component with an instantaneous frequency below the first threshold, a rectangular window type suitable for the low-frequency band is selected. For a signal component with a moderate frequency, that is, a signal component with an instantaneous frequency greater than the first threshold and below a second threshold, a Hanning window type suitable for a moderate-frequency band is selected. For a signal component with a high frequency, that is, a signal component with an instantaneous frequency greater than the second threshold and below a third threshold, a Blackman window type suitable for a high-frequency band is selected.

In the time-frequency conversion algorithm, it is required to use a window function to extract a certain length of signal from the signal component in the time domain for sampling and calculation. The length of the extracted signal is equal to the sampling window length. A longer sampling window length indicates a higher frequency resolution and a higher calculation complexity. The frequency analysis at different frequencies has different requirements for accuracy and speed. Therefore, in an embodiment, the time-frequency conversion parameter configured based on the instantaneous frequency further includes a sampling window length. Specifically, the following steps are performed: (1) determining a target cycle number based on a mapping relationship between instantaneous frequencies and cycle numbers; (2) determining a cycle length based on the instantaneous frequency; and (3) obtaining the sampling window length based on the cycle length and the target cycle number.

It should be understood that in the embodiment, the sampling window length is determined in units of cycles. The target cycle number represents the number of cycles included in the sampling window at the instantaneous frequency. Target cycle numbers corresponding to different instantaneous frequencies may be predetermined, that is, a mapping relationship between the instantaneous frequencies and the cycle numbers may be predetermined. After determining an instantaneous frequency of a signal component, a cycle length may be determined according to the mapping relationship. Therefore, the sampling window length may be obtained by multiplying the target cycle number and the cycle length. The cycle length and the instantaneous frequency are reciprocal to each other. Therefore, after determining the target cycle number and the cycle length based on the instantaneous frequency, the sampling window length corresponding to the signal component may be determined. In addition, even if two signal components have a same target cycle number, the sampling window lengths are different due to the different cycle lengths of the two signal components, so that the frequency resolutions of the two signal components vary adaptively depending on the different instantaneous frequencies. According to the conventional technology, discrete Fourier transform is perform on an undecomposed target electrical signal with a same time window length, and the entire frequency band has a same frequency resolution, which is not conducive to the adaptive analysis for different frequencies.

In an embodiment, the target cycle number is determined based on the mapping relationship between instantaneous frequencies and cycle numbers by: (1) determining the target cycle number as a first number in the case that the instantaneous frequency is below the first threshold; (2) determining the target cycle number as a second number in the case that the instantaneous frequency is greater than the first threshold and below the second threshold, where the second number is greater than the first number; and (3) determining the target cycle number as a third number in the case that the instantaneous frequency is greater than the second threshold and below the third threshold. The third number is greater than the first number and less than the second number.

It should be understood that the third threshold is an upper limit of the target frequency band for wideband measurement. The target frequency band is divided into three sections based on the first threshold and the second threshold. Signals with frequencies below the first threshold have a significant impact on the stability and safety of the power grid and should be determined as soon as possible, and calculation efficiency should be prioritized, so that the target cycle number corresponding to the signals with frequencies below the first threshold is the first number which is the smallest one of the three numbers. Signals with frequencies greater than the first threshold and below the second threshold are signals related to power quality assessment. Power system managers trace the sources of introduced harmonics based on detection results and then hold accountable. As the basis for accountability, the detection results should have a high accuracy. Calculation accuracy should be prioritized. Therefore, the target cycle number corresponding to the signals with frequencies greater than the first threshold and below the second threshold is the second number which is the largest one of the three numbers. There are fewer signals with frequencies greater than the first threshold and below the second threshold. Considering the calculation efficiency and the short cycle length, the target cycle number is determined as the third number which is greater than the first number and less than the second number. In an embodiment, the first threshold is 100 Hz, the second threshold is 650 Hz, the third threshold is 2500 Hz, the first number is 2, the second number is 8, and the third number is 3.

In an embodiment, the target electrical signal is decomposed into the multiple single-frequency signal components in the time domain using the local mean decomposition algorithm by performing the following steps (1) to (10).

In step (1), a current target electrical signal is used as an intermediate electrical signal.

In step (2), all local maximum points and local minimum points of the intermediate electrical signal are determined.

That is, the target electrical signal is traversed, and local extremum points of amplitude are determined. It is assumed that x(t) represents the intermediate electrical signal, then a sequence x(n) is obtained by sampling x(t). The discriminant of local maximum points may be expressed as:

(x(n−1)<x(n)&&(x(n)>x(n+1)

The discriminant of local minimum points may be expressed as:

(x(n−1)>x(n)&&(x(n)<x(n+1)

In step (3), cubic spline interpolation is performed on the local maximum points to obtain an upper envelope function, and cubic spline interpolation is performed on the local minimum points to obtain a lower envelope function.

Cubic spline interpolation is a numerical calculation algorithm. With the numerical calculation algorithm, a set of cubic polynomial functions may be used to approximate a given set of discrete data points, so that all the function satisfies an interpolation condition on corresponding subintervals and maintains the continuity of function values, first-order derivatives, and second-order derivatives at the connections of all the subintervals. Therefore, with the cubic spline interpolation, the local maximum points and the local minimum points may be respectively fitted as a continuous upper envelope function and a continuous lower envelope function in the time domain.

In step (4), a local mean function and a local envelope function in a current cycle are obtained based on the upper envelope function and the lower envelope function.

Specifically, the local mean function and the local envelope function may be respectively expressed as:

$${m}_{i} ( t ) = \frac{{Env}_{m ax} ( t ) + {Env}_{m i n} ( t )}{2} , {a}_{i} ( t ) = \vert \frac{{Env}_{ma x} ( t ) - {Env}_{m i n} ( t )}{2} \vert$$

where mᵢ(t) represents a local mean function in an i-th cycle, aᵢ(t) represents a local envelope function in the i-th cycle, Envₘₐₓ(t) represents the upper envelope function, and Envₘᵢₙ(t) represents the lower envelope function.

In step (5), it is determined whether the local envelope function in the current cycle is equal to 1.

It should be understood that the local mean decomposition algorithm is a double loop algorithm. In an outer loop, a newly obtained signal component is subtracted from the target electrical signal each time to obtain a current target electrical signal. Then, an inner loop is performed with the current target electrical signal as an intermediate electrical signal. In the inner loop, a signal component is decomposed from the intermediate electrical signal. In separating the signal component, it is determined whether the separation is completed based on whether the local envelope function is equal to 1. In a case that the local envelope function is equal to 1, it indicates that the local mean function in a current cycle is a pure frequency modulation function. All the local envelope functions in a current inner loop are multiplied to obtain an envelope signal (that is, an amplitude signal) of the pure frequency modulation function. The envelope signal is multiplied with the pure frequency modulation signal to obtain the signal component in the current inner loop. It can be seen that in the inner loop, it is determined whether the local envelope function in the current cycle is equal to 1, and then based on a determination result, proceed to step (6) to continue the current inner loop or proceed to step (7) to end the current inner loop.

In step (6), in a case that the local envelope function in the current cycle is not equal to 1, a difference between the intermediate electrical signal and the local mean function is divided by the local envelope function, and then return to the step of determining all local maximum points and local minimum points of the intermediate electrical signal.

In step (7), in a case that the local envelope function in the current cycle is equal to 1, the local envelope function in the current cycle and local envelope functions in all previous cycles are multiplied to obtain an envelope signal, the local mean function in the current cycle is used as a pure frequency modulation signal, and a signal component is obtained based on the envelope signal and the pure frequency modulation signal.

In step (8), it is determined whether an iteration end condition is met after obtaining the signal component

It should be understood that the iteration end condition here refers to a condition for ending the outer loop, that is, all required signal components have been decomposed from the target electrical signal. In some embodiments, the step (8) may include: determining that the iteration end condition is met in a case that the number of local maximum points and local minimum points of an obtained signal component is less than a first threshold; and determining that the iteration end condition is not met in a case that the number of local maximum points and local minimum points of an obtained signal component is not less than a first threshold. It should be understood that the principle of the above determination is that in the case that the number of local extremum points is less than the first threshold, the frequency of the signal component is low and the target electrical signal, after subtracting multiple signal components, contains fewer frequency components, and further decomposition is meaningless, so that decomposition may be stopped. The first threshold may be 20. After the current inner loop ends, it is determined whether the iteration end condition is met, and then based on the determination result, proceed to step (9) to start a next inner loop to perform decomposition to obtain signal components or proceed to step (10) to end the outer loop.

In step (9), in a case that the iteration end condition is not met, the obtained signal component is subtracted from the target electrical signal, and return to the step of determining all local maximum points and local minimum points of the target electrical signal.

In step (10), in a case that the iteration end condition is met, the decomposing the target electrical signal into multiple single-frequency signal components in the time domain is ended.

An analysis and verification example is provided for the method according to the present disclosure. Analysis is provided based on the following simulation signal:

x(t)=(1+0.25 cos(2π*110t))(0.25 cos(2π*1100t))+5 cos(2π*50t)

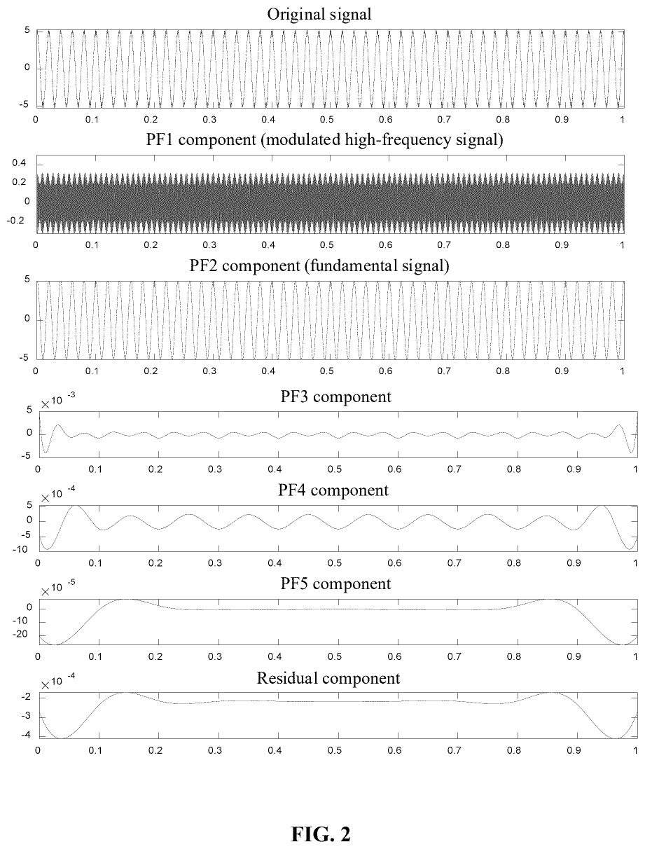

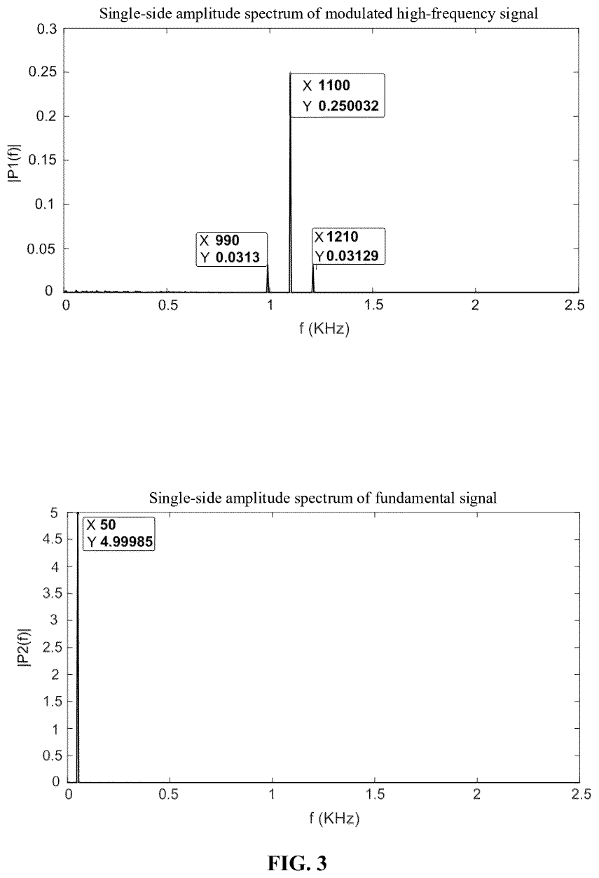

The simulation signal is formed by superimposing a high-frequency modulation signal (where 1+0.25 cos (2π*110t) represents an amplitude modulation component) with a frequency of 1100 Hz and an amplitude of 0.25 and a power frequency signal with an amplitude of 5. Firstly, the simulation signal is decomposed by using the local mean decomposition algorithm to obtain an envelope signal and a corresponding pure frequency modulation signal. Based on a product of the envelope signal and the pure frequency modulation signal, all single-frequency signal components and residual components are obtained. The obtained PF components are sorted in descending order of frequency. FIG. 2 shows a schematic diagram of decomposing a simulation signal. Analysis is provided based on data of a PF1 component and a PF2 component. The PF1 component contains time-frequency features of a high-frequency modulation signal in the simulation signal, and the PF2 component contains time-frequency features of the power frequency signal. The mean square error of the PF1 component is 0.0049, and the mean square error of the PF2 component is 2.8532*10⁻⁵. Therefore, the reconstruction accuracy of the local mean decomposition algorithm used in the present disclosure can effectively meet practical requirements and can effectively extract the features of wideband resonant signal sequences. After extracting the features of the wideband resonant signal sequence, DFT calculation is performed respectively on the PF1 component and the PF2 component using corresponding time windows. FIG. 3 shows a schematic diagram of finally obtained amplitude spectra of the PF1 component and the PF2 component. It can be seen that the frequency of the high-frequency modulation signal is 1100 Hz and the amplitude of the obtained high-frequency modulation signal is 0.250032, and the frequency of the power frequency signal is 50 Hz and the amplitude of the power frequency signal is 4.99985. The experimental results indicate that the amplitude and frequency obtained by feature extraction and analysis of the single-frequency PF components are consistent with the simulation signal. From the above experimental results, it can be seen that with the method according to the present disclosure, the features in the wideband resonant signal sequence can be accurately extracted, and the method according to the present disclosure is feasible and can be used for processing and analyzing the wideband signals in power systems, effectively meeting wideband measurement requirements of new power systems and providing strong support for constructing a wide-area monitoring system for wideband oscillation in the power system.

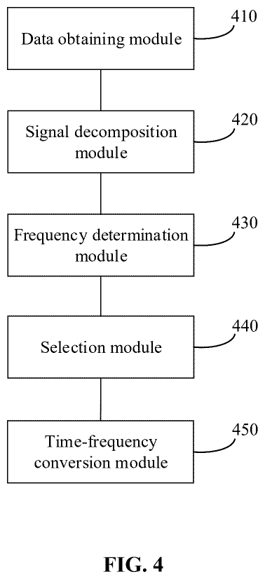

A wideband measurement apparatus for a power system is provided according to the present disclosure. Referring to FIG. 4, the apparatus includes a data obtaining module 410, a signal decomposition module 420, a frequency determination module 430, a selection module 440, and a time-frequency conversion module 450.

The data obtaining module 410 is configured to obtain a target electrical signal.

The signal decomposition module 420 is configured to decompose the target electrical signal into multiple single-frequency signal components in a time domain by using a local mean decomposition algorithm.

The frequency determination module 430 is configured to determine, for each of the signal components, an instantaneous frequency of the signal component.

The selection module 440 is configured to determine, for each of the signal components, a time-frequency conversion algorithm and a time-frequency conversion parameter based on the instantaneous frequency.

The time-frequency conversion module 450 is configured to: perform, for each of the signal components, time-frequency conversion on the signal component corresponding to the time-frequency conversion parameter by using the time-frequency conversion algorithm based on the time-frequency conversion parameter, and obtain a wideband spectrum including frequency-domain information corresponding to all the signal components.

In an embodiment, the selection module 440 is configured to: determine the time-frequency conversion algorithm as a discrete Fourier algorithm in a case that the instantaneous frequency is below a first threshold; and determine the time-frequency conversion algorithm as a fast Fourier algorithm in a case that the instantaneous frequency is greater than the first threshold.

In an embodiment, the time-frequency conversion parameter includes a sampling window type. The selection module 440 is configured to: determine the sampling window type as a rectangular window type in the case that the instantaneous frequency is below the first threshold; determine the sampling window type as a Hanning window type in a case that the instantaneous frequency is greater than the first threshold and below a second threshold; and determine the sampling window type as a Blackman window type in a case that the instantaneous frequency is greater than the second threshold and below a third threshold.

In an embodiment, the selection module 440 is configured to: determine a target cycle number based on a mapping relationship between instantaneous frequencies and cycle numbers; determine a cycle length based on the instantaneous frequency; and obtain a sampling window length based on the cycle length and the target cycle number.

In an embodiment, the selection module 440 is configured to: determine the target cycle number as a first number in the case that the instantaneous frequency is below the first threshold; determine the target cycle number as a second number in the case that the instantaneous frequency is greater than the first threshold and below the second threshold, where the second number is greater than the first number; and determine the target cycle number as a third number in the case that the instantaneous frequency is greater than the second threshold and below the third threshold, where the third number is greater than the first number and less than the second number.

In an embodiment, the signal decomposition module 420 is configured to: use the target electrical signal as an intermediate electrical signal; determine all local maximum points and local minimum points of the intermediate electrical signal; perform cubic spline interpolation on the local maximum points to obtain an upper envelope function, and perform cubic spline interpolation on the local minimum points to obtain a lower envelope function; obtain a local mean function and a local envelope function in a current cycle based on the upper envelope function and the lower envelope function; determine whether the local envelope function in the current cycle is equal to 1; divide a difference between the intermediate electrical signal and the local mean function by the local envelope function, and return to the step of determining all local maximum points and local minimum points of the intermediate electrical signal, in a case that the local envelope function in the current cycle is not equal to 1; multiply the local envelope function in the current cycle and local envelope functions in all previous cycles to obtain an envelope signal, use the local mean function in the current cycle as a pure frequency modulation signal, and obtain a signal component based on the envelope signal and the pure frequency modulation signal, in a case that the local envelope function in the current cycle is equal to 1; determine whether an iteration end condition is met after obtaining the signal component; subtract the obtained signal component from the target electrical signal, and return to the step of using the target electrical signal as an intermediate electrical signal, in a case that the iteration end condition is not met; and end the decomposing the target electrical signal into multiple single-frequency signal components in a case that the iteration end condition is met.

The specific limitations of the wideband measurement apparatus for a power system may refer to the limitations of the wideband measurement method for a power system mentioned above, and are not repeated herein. The modules in the wideband measurement apparatus for a power system may be fully or partially implemented through software, hardware and a combination thereof. The modules may be embedded in or independent of the processor of the computer device in a hardware form, or may be stored in the memory of the computer device in a software form for facilitating the processor calling and executing the operations corresponding to the above modules. It should be noted that the division of modules in the embodiments of the present disclosure is schematic and is only a logical function division, and different divisions may be performed in actual implementations.

A computer device is provided according to the present disclosure. The computer device includes: one or more processors and a memory. The memory stores computer-readable instructions. The computer-readable instructions, when executed by the one or more processors, cause the one or more processors to perform the wideband measurement method for a power system described in the above embodiments.

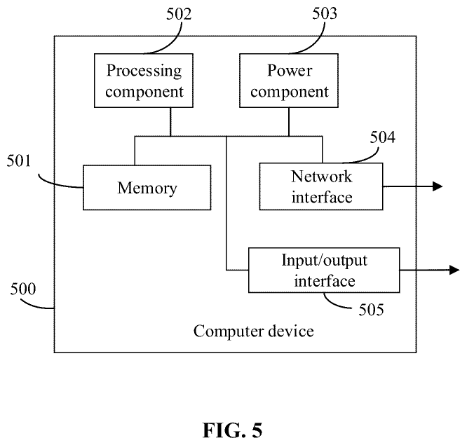

As shown in FIG. 5, FIG. 5 is a schematic diagram showing an internal structure of a computer device according to an embodiment of the present disclosure. Referring to FIG. 5, the computer device 500 includes: a processing component 502 which further includes one or more processors, and a memory resource represented by the memory 501 for storing instructions, such as an application program, executed by the processing component 502. The memory 501 may store one or more application programs, each of which corresponds to a set of instructions. In addition, the processing component 502 is configured to execute instructions to perform the wideband measurement method for a power system according to any one of the above embodiments.

The computer device 500 may further include: a power component 503 configured to perform power management on the computer device 500, a wired or wireless network interface 504 configured to connect the computer device 500 to a network, and an input/output (I/O) interface 505.

Those skilled in the art should understand that the structure shown in FIG. 5 only includes part blocks related to the solutions of the present disclosure, and does not limit the computer device to which the solutions of the present disclosure is applied. The specific computer device may include more or fewer components than shown in FIG. 5, or combine certain components, or have different component arrangements.

A storage medium is provided according to the present disclosure. The storage medium stores computer-readable instructions. The computer-readable instructions, when being executed by one or more processors, cause the one or more processors to perform the wideband measurement method for a power system according to any one of the above embodiments.

The embodiments in this specification are described in a progressive manner, and each embodiment emphasizes the differences from other embodiments. The embodiments may be combined as required, and the same or similar parts may be referred to each other.

According to the descriptions of the embodiments of the present disclosure, those skilled in the art may implement or use the present disclosure. Modifications to these embodiments are apparent for those skilled in the art. The general principles defined in this specification may be implemented in other embodiments without departing from the spirit or scope of the present disclosure. Therefore, the present disclosure is not to be limited to the embodiments in the present disclosure, and conform to the widest scope consistent with the principles and novel features disclosed in the present disclosure.

1. A wideband measurement method for a power system, comprising:
obtaining a target electrical signal;
decomposing the target electrical signal into a plurality of single-frequency signal components in a time domain by using a local mean decomposition algorithm;
for each of the plurality of single-frequency signal components,
determining an instantaneous frequency of the signal component;
determining a time-frequency conversion algorithm and a time-frequency conversion parameter based on the instantaneous frequency; and
performing time-frequency conversion on the signal component by using the time-frequency conversion algorithm based on the time-frequency conversion parameter; and
obtaining a wideband spectrum comprising frequency-domain information corresponding to all the plurality of single-frequency signal components.

2. The wideband measurement method for a power system according to claim 1, wherein the determining a time-frequency conversion algorithm based on the instantaneous frequency comprises:
determining the time-frequency conversion algorithm as a discrete Fourier algorithm in a case that the instantaneous frequency is below a first threshold; and
determining the time-frequency conversion algorithm as a fast Fourier algorithm in a case that the instantaneous frequency is greater than the first threshold.

3. The wideband measurement method for a power system according to claim 2, wherein the time-frequency conversion parameter comprises a sampling window type, and the determining a time-frequency conversion parameter based on the instantaneous frequency comprises:
determining the sampling window type as a rectangular window type in the case that the instantaneous frequency is below the first threshold;
determining the sampling window type as a Hanning window type in a case that the instantaneous frequency is greater than the first threshold and below a second threshold; and
determining the sampling window type as a Blackman window type in a case that the instantaneous frequency is greater than the second threshold and below a third threshold.

4. The wideband measurement method for a power system according to claim 3, wherein the time-frequency conversion parameter comprises a sampling window length, and the determining a time-frequency conversion parameter based on the instantaneous frequency comprises:
determining a target cycle number based on a mapping relationship between instantaneous frequencies and cycle numbers;
determining a cycle length based on the instantaneous frequency; and
obtaining the sampling window length based on the cycle length and the target cycle number.

5. The wideband measurement method for a power system according to claim 4, wherein the determining a target cycle number based on a mapping relationship between instantaneous frequencies and cycle numbers comprises:
determining the target cycle number as a first number in the case that the instantaneous frequency is below the first threshold;
determining the target cycle number as a second number in the case that the instantaneous frequency is greater than the first threshold and below the second threshold, wherein the second number is greater than the first number; and
determining the target cycle number as a third number in the case that the instantaneous frequency is greater than the second threshold and below the third threshold, wherein the third number is greater than the first number and less than the second number.

6. The wideband measurement method for a power system according to claim 5, wherein the first threshold is 100 Hz, the second threshold is 650 Hz, the third threshold is 2500 Hz, the first number is 2, the second number is 8, and the third number is 3.

7. The wideband measurement method for a power system according to claim 1, wherein the decomposing the target electrical signal into a plurality of single-frequency signal components in a time domain by using a local mean decomposition algorithm comprises:
using the target electrical signal as an intermediate electrical signal;
determining all local maximum points and local minimum points of the intermediate electrical signal;
performing cubic spline interpolation on the local maximum points to obtain an upper envelope function, and performing cubic spline interpolation on the local minimum points to obtain a lower envelope function;
obtaining a local mean function and a local envelope function in a current cycle based on the upper envelope function and the lower envelope function;
determining whether the local envelope function in the current cycle is equal to 1;
dividing a difference between the intermediate electrical signal and the local mean function by the local envelope function, and returning to the determining all local maximum points and local minimum points of the intermediate electrical signal, in a case that the local envelope function in the current cycle is not equal to 1;
multiplying the local envelope function in the current cycle and local envelope functions in all previous cycles to obtain an envelope signal, using the local mean function in the current cycle as a pure frequency modulation signal, and obtaining a signal component based on the envelope signal and the pure frequency modulation signal, in a case that the local envelope function in the current cycle is equal to 1;
determining whether an iteration end condition is met after obtaining the signal component;
subtracting the obtained signal component from the target electrical signal, and returning to the using the target electrical signal as an intermediate electrical signal, in a case that the iteration end condition is not met; and
ending the decomposing the target electrical signal into a plurality of single-frequency signal components in a case that the iteration end condition is met.

8. The wideband measurement method for a power system according to claim 7, wherein the determining whether an iteration end condition is met comprises:
determining that the iteration end condition is met in a case that the number of local maximum points and local minimum points in the obtained signal component is less than a first threshold; and
determining that the iteration end condition is not met in a case that the number of local maximum points and local minimum points in the obtained signal component is not less than the first threshold.

9. A wideband measurement apparatus for a power system, comprising:
a data obtaining module, configured to obtain a target electrical signal;
a signal decomposition module, configured to decompose the target electrical signal into a plurality of single-frequency signal components in a time domain by using a local mean decomposition algorithm;
a frequency determination module, configured to determine, for each of the signal components, an instantaneous frequency of the signal component;
a selection module, configured to determine, for each of the signal components, a time-frequency conversion algorithm and a time-frequency conversion parameter based on the instantaneous frequency; and
a time-frequency conversion module, configured to: perform, for each of the signal components, time-frequency conversion on the signal component by using the time-frequency conversion algorithm based on the time-frequency conversion parameter, and obtain a wideband spectrum comprising frequency-domain information corresponding to all the signal components.

10. A computer device, comprising:
one or more processors; and
a memory, storing computer-readable instructions, wherein
the computer-readable instructions, when executed by the one or more processors, cause the one or more processors to perform the wideband measurement method for a power system according to claim 1.
